(19) United States
(12) Patent Application Publication
(10) Pub. No.: US 2025/0301621 A1
(43) Pub. Date: Sep. 25, 2025

(54) ASYMMETRICAL CAPACITOR HAVING LOW LEAKAGE CURRENT AND MEMORY CELL USING THE SAME

(71) Applicant: TAIWAN SEMICONDUCTOR MANUFACTURING COMPANY, LTD., Hsinchu (TW)

(72) Inventors: Kuen-Yi Chen, Hsinchu (TW); Yi Ching ONG, Hsinchu (TW); Wei Ting HSIEH, Hsinchu (TW); Yu-Wei TING, Hsinchu (TW); Kuo-Ching HUANG, Hsinchu (TW)

(73) Assignee: TAIWAN SEMICONDUCTOR MANUFACTURING COMPANY, LTD., Hsinchu (TW)

(21) Appl. No.: 18/610,441

(22) Filed: Mar. 20, 2024

(51) Int. Cl. H10B 12/00

(52) U.S. Cl. CPC H10B 12/00

(57) ABSTRACT

An asymmetrical capacitor includes a first electrode, a second electrode and a dielectric element. The dielectric element is sandwiched between the first electrode and the second electrode. The first electrode has a work function that is greater than a work function of the second electrode by at least 0.2 eV.

### BACKGROUND

A capacitor can be used in a memory cell to store data. The capacitor needs to have low leakage current, so that the memory cell can have good data retention performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic perspective view of an asymmetrical capacitor in accordance with some embodiments.

FIG. 2 is a schematic sectional view of an asymmetrical capacitor in accordance with some embodiments.

FIG. 3 is a circuit diagram illustrating a memory cell in accordance with some embodiments.

FIG. 4 is a plot illustrating leakage current density versus electrical field characteristic of a comparative capacitor.

FIG. 5 is a plot illustrating data retention performance of a comparative memory cell.

FIG. 6 is a plot illustrating leakage current density versus electrical field characteristic of the asymmetrical capacitor of FIG. 1.

FIG. 7 is a plot illustrating data retention performance of the memory cell of FIG. 3.

FIG. 8 is a circuit diagram illustrating a memory cell in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly.

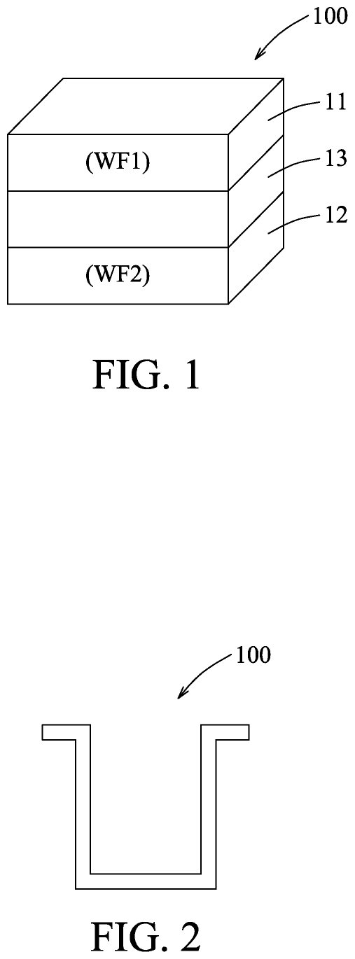

FIG. 1 is a schematic perspective view of an asymmetrical capacitor 100 in accordance with some embodiments. Referring to FIG. 1, the asymmetrical capacitor 100 includes a first electrode 11, a second electrode 12 and a dielectric element 13. The first electrode 11 is disposed above and spaced apart from the second electrode 12. The dielectric element 13 is sandwiched between the first electrode 11 and the second electrode 12. The first electrode 11 has a work function of WF1. The second electrode 12 has a work function of WF2. The work function of the first electrode 11 and the work function of the second electrode 12 are different from each other (i.e., WF1+WF2).

In some embodiments, the work function of the first electrode 11 may be greater than the work function of the second electrode 12 by at least 0.2 eV (i.e., WF1−WF2≥0.2 eV). In some embodiments, the work function of the first electrode 11 may be greater than the work function of the second electrode 12 by at most 1.5 eV (i.e., WF1−WF2≤1.5 eV). In a scenario where a voltage at the first electrode 11 is greater than a voltage at the second electrode 12 by a predetermined amount, the asymmetrical capacitor 100, in which the work function of the first electrode 11 is greater than the work function of the second electrode 12 and a difference between the work function of the first electrode 11 and the work function of the second electrode 12 falls within a range of from 0.2 eV to 1.5 eV (i.e., 0.2 eV≤WF1−WF2≤1.5 eV), can have an apparently small leakage current as compared to a comparative capacitor, in which the work function of the first electrode 11 is equal to the work function of the second electrode 12 (i.e., WF1−WF2=0 eV). This is beneficial to reducing a thickness of the dielectric element 13, which results in an increase in a capacitance of the asymmetrical capacitor 100. If the work function of the first electrode 11 is greater than the work function of the second electrode 12 but the difference between the work function of the first electrode 11 and the work function of the second electrode 12 is smaller than 0.2 eV (i.e., 0 eV<WF1−WF2<0.2 eV), a difference between the leakage current of the asymmetrical capacitor 100 and a leakage current of the comparative capacitor may be very small. If the work function of the first electrode 11 is greater than the work function of the second electrode 12 but the difference between the work function of the first electrode 11 and the work function of the second electrode 12 is greater than 1.5 eV (i.e., WF1−WF2>1.5 eV), the leakage current of the asymmetrical capacitor 100 may be very large in a scenario where the voltage at the first electrode 11 is equal to the voltage at the second electrode 12.

The asymmetrical capacitor 100 can be fabricated in the back-end-of-line (BEOL). In some embodiments, the asymmetrical capacitor 100 may have a two-dimensional (2D) structure as depicted in FIG. 1. In some embodiments, the asymmetrical capacitor 100 may have a three-dimensional (3D) structure as depicted in FIG. 2, so an active area of the asymmetrical capacitor 100 and thus the capacitance of the asymmetrical capacitor 100 can be raised by increasing a height of the asymmetrical capacitor 100 while keeping unchanged an area of a projection of the asymmetrical capacitor 100 on a horizontal plane.

In some embodiments, each of the first electrode 11 and the second electrode 12 may be made of a conductive material, for example, but not limited to, pure metal, refractory metal nitride, conductive oxide, or combinations thereof. Other suitable conductive materials are within the contemplated scope of the present disclosure.

In some embodiments, each of the first electrode 11 and the second electrode 12 may have a thickness that is smaller than or equal to 30 nm. When the thickness of any one of the first electrode 11 and the second electrode 12 is greater than 30 nm, the asymmetrical capacitor 100 may have a very large thickness, but this would not affect the characteristics of the asymmetrical capacitor 100.

In some embodiments, the first electrode 11 and the second electrode 12 may be made of different materials, so the work function of the first electrode 11 and the work function of the second electrode 12 can be different from each other. For example, the first electrode 11 is made of ruthenium that has a work function of about 5 eV, and the second electrode is made of tantalum that has a work function of about 4 eV.

In some embodiments, the first electrode 11 and the second electrode 12 may be made of the same material, but may have different crystalline orientations and/or different crystalline phases (e.g., having different crystalline orientations but the same crystalline phases, having the same crystalline orientations but different crystalline phases, or having different crystalline orientations and different crystalline phases), so the work function of the first electrode 11 and the work function of the second electrode 12 can be different from each other. For example, the first electrode 11 and the second electrode 12 are made of the same material and have the same crystalline phases, but the first electrode 11 has a crystalline orientation of (1, 1, 1) while the second electrode 12 has a crystalline orientation of (2, 0, 0).

In some embodiments, the first electrode 11 and the second electrode 12 may be made of the same material, but may have different composition ratios, so the work function of the first electrode 11 and the work function of the second electrode 12 can be different from each other. For example, the first electrode 11 and the second electrode 12 are made of tantalum nitride, but an atomic percent of nitrogen in the first electrode 11 is different from an atomic percent of nitrogen in the second electrode 12.

In some embodiments, the dielectric element 13 may have a dielectric constant that is greater than or equal to 30, so the asymmetrical capacitor 100 can have a large capacitance even when having a two-dimensional structure.

In some embodiments, the dielectric element 13 may have a thickness that is smaller than or equal to 10 nm, so the asymmetrical capacitor 100 can have a large capacitance even when having a two-dimensional structure.

In some embodiments, the dielectric element 13 may be made of oxide, perovskite oxide, nitride, oxy-nitride, or combinations thereof (for example, but not limited to, zirconium oxide, hafnium oxide, titanium oxide, barium titanium oxide, strontium titanium oxide, hafnium zirconium oxide, hafnium oxy-nitride, zirconium oxy-nitride, or the like). Other suitable materials are within the contemplated scope of the present disclosure.

In some embodiments, the dielectric element 13 may include a single layer that has a symmetrical crystalline phase structure (for example, but not limited to, a tetragonal crystalline phase structure, a cubic crystalline phase structure, or the like). Other suitable symmetrical crystalline phase structures are within the contemplated scope of the present disclosure. For example, the dielectric element 13 includes a single layer of zirconium oxide or titanium oxide.

In some embodiments, the dielectric element 13 may include a plurality of layers, each of which has a symmetrical crystalline phase structure (for example, but not limited to, a tetragonal crystalline phase structure, a cubic crystalline phase structure, or the like). Other suitable symmetrical crystalline phase structures are within the contemplated scope of the present disclosure. For example, the dielectric element 13 may include a layer of zirconium oxide, a layer of aluminum oxide and a layer of zirconium oxide, or may include a layer of aluminum oxide and a layer of zirconium oxide.

In some embodiments, the dielectric element 13 may be made of a compound material that has a morphotropic phase boundary (for example, but not limited to, hafnium zirconium oxide, or the like).

The asymmetrical capacitor 100 can be applied in an embedded device such as an embedded memory device (e.g., an L2 or L3 cache, a gain cell random access memory (GCRAM), etc.). Other suitable applications are within the contemplated scope of the present disclosure.

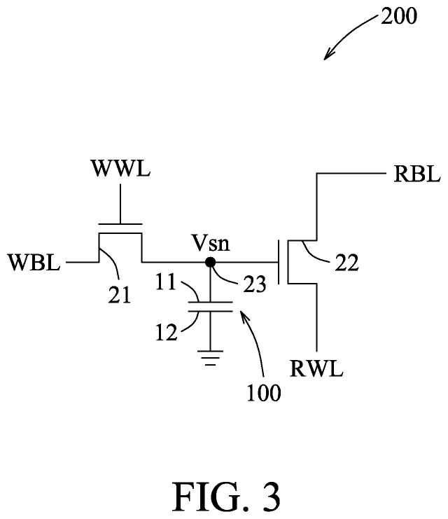

FIG. 3 is a circuit diagram illustrating a memory cell 200 in accordance with some embodiments. Referring to FIG. 3, the memory cell 200 has a 2T1C structure, and can be used in a gain cell random access memory. The memory cell 200 includes a first transistor 21, a second transistor 22 and the asymmetrical capacitor 100 as depicted in FIG. 1. The first transistor 21 (e.g., an N-channel metal oxide semiconductor field effect transistor (nMOSFET)) has a first terminal (e.g., a source terminal) that is connected to a write bit line (WBL), a second terminal (e.g., a drain terminal) that is connected to a storage node 23, and a control terminal (e.g., a gate terminal) that is connected to a write word line (WWL). The second transistor 22 (e.g., an N-channel metal oxide semiconductor field effect transistor) has a first terminal (e.g., a source terminal) that is connected to a read word line (RWL), a second terminal (e.g., a drain terminal) that is connected to a read bit line (RBL), and a control terminal (e.g., a gate terminal) that is connected to the storage node 23. The first electrode 11 of the asymmetrical capacitor 100 is connected to the storage node 23. The second electrode 12 of the asymmetrical capacitor 100 is connected to ground.

To write a bit of a logic value “1” to the memory cell 200, a supply voltage (>0 volts) is provided to the write bit line (WBL), and the supply voltage is further provided to the write word line (WWL) so as to make the first transistor 21 conducting. The bit of the logic value “1” is transmitted from the write bit line (WBL) to the storage node 23 through the conducting first transistor 21, so a voltage (Vsn) at the storage node 23 approaches the supply voltage. After the write “1” operation is performed on the memory cell 200, the bit of the logic value “1” is kept at the storage node 23.

To write a bit of a logic value “0” to the memory cell 200, a ground voltage of 0 volts is provided to the write bit line (WBL), and the supply voltage is provided to the write word line (WWL) so as to make the first transistor 21 conducting. The bit of the logic value “0” is transmitted from the write bit line (WBL) to the storage node 23 through the conducting first transistor 21, so the voltage (Vsn) at the storage node 23 approaches the ground voltage. After the write “0” operation is performed on the memory cell 200, the bit of the logic value “0” is kept at the storage node 23.

To read the bit of data from the memory cell 200, the read bit line (RBL) is precharged to the supply voltage, the ground voltage is provided to the read word line (RWL), and the ground voltage is further provided to the write word line (WWL) so as to make the first transistor 21 non-conducting. If the bit of data kept at the storage node 23 is the bit of the logic value “1,” then the second transistor 22 would conduct, and the read bit line (RBL) would be discharged by ground through the conducting second transistor 22 so as to fall to a voltage approaching the ground voltage. If the bit of data kept at the storage node is the bit of the logic value “0,” then the second transistor 22 would not conduct, and the read bit line (RBL) would stay precharged to the supply voltage.

The memory cell 200 that utilizes the asymmetrical capacitor 100 can be fabricated without using additional mask layers, and thus can have a low fabrication cost.

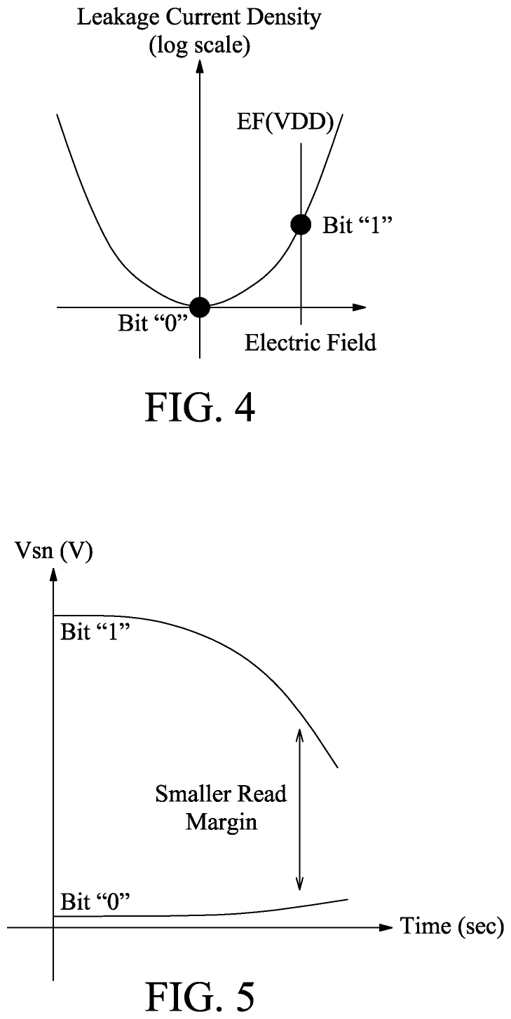

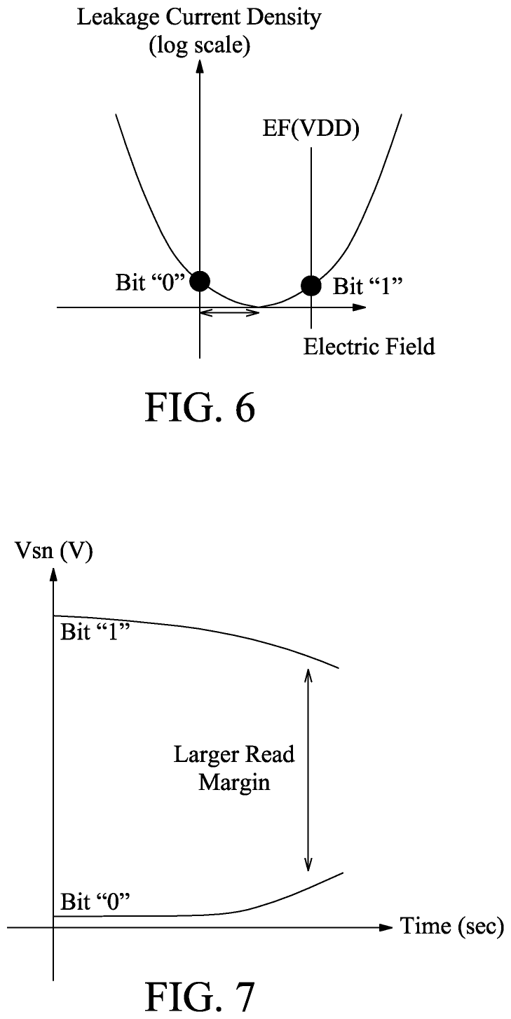

FIG. 4 is a plot illustrating leakage current density versus electrical field characteristic of the comparative capacitor, in which the work function of the first electrode 11 is equal to the work function of the second electrode 12. FIG. 5 is a plot illustrating data retention performance of a comparative memory cell that includes the comparative capacitor instead of the asymmetrical capacitor 100 as depicted in FIG. 1. FIG. 6 is a plot illustrating leakage current density versus electrical field characteristic of the asymmetrical capacitor 100 as depicted in FIG. 1. FIG. 7 is a plot illustrating data retention performance of the memory cell 200 as depicted in FIG. 3. As shown in FIGS. 4 and 6, with respect to each of the comparative capacitor and the asymmetrical capacitor 100 as depicted in FIG. 1, the leakage current density of the capacitor is positively correlated to the leakage current of the capacitor, and the electric field of the capacitor is positively correlated to the voltage (Vsn) at the storage node 23. As shown in FIG. 6, the shift of the leakage current density versus electrical field curve is related to the difference between the work function of the first electrode 11 and the work function of the second electrode 12 of the asymmetrical capacitor 100 as depicted in FIG. 1, where the leakage current density versus electrical field curve is shifted to the right when the work function of the first electrode 11 is greater than the work function of the second electrode 12, and is shifted to the left when the work function of the first electrode 11 is smaller than the work function of the second electrode 12. As shown in FIG. 4, the leakage current of the comparative capacitor increases with an increase of the voltage (Vsn) at the storage node 23 when the voltage (Vsn) at the storage node 23 is greater than the ground voltage, increases with a decrease of the voltage (Vsn) at the storage node 23 when the voltage (Vsn) at the storage node 23 is smaller than the ground voltage, and reaches its minimum when the voltage (Vsn) at the storage node 23 is equal to the ground voltage. As shown in FIG. 6, the leakage current of the asymmetrical capacitor 100 as depicted in FIG. 1 increases with an increase of the voltage (Vsn) at the storage node 23 when the voltage (Vsn) at the storage node 23 is greater than a transition voltage corresponding to the difference in work function between the first electrode 11 and the second electrode 12, increases with a decrease of the voltage (Vsn) at the storage node 23 when the voltage (Vsn) at the storage node 23 is smaller than the transition voltage, and reaches its minimum when the voltage (Vsn) at the storage node 23 is equal to the transition voltage. It can be reasonably determined from FIGS. 4 and 6 that the leakage current of the asymmetrical capacitor 100 is much smaller than the leakage current of the comparative capacitor when both of the memory cell 200 as depicted in FIG. 3 and the comparative memory cell store the bit of the logic value “1,” and is slightly larger than the leakage current of the comparative capacitor when both of the memory cell 200 as depicted in FIG. 3 and the comparative memory cell store the bit of the logic value “0,” so, as shown in FIGS. 5 and 7, the voltage (Vsn) at the storage node 23 of the memory cell 200 as depicted in FIG. 3 decreases much slower over time and thus the memory cell 200 as depicted in FIG. 3 has better data retention performance as compared to the comparative memory cell after the write “1” operation is performed on both of the memory cell 200 as depicted in FIG. 3 and the comparative memory cell, and increases over time slightly faster as compared to the comparative memory cell after the write “0” operation is performed on both of the memory cell 200 as depicted in FIG. 3 and the comparative memory cell, and the memory cell 200 as depicted in FIG. 3 can have a larger read margin as compared to the comparative memory cell.

In some embodiments, one or both of the first transistor 21 and the second transistor 22 of the memory cell 200 as depicted in FIG. 3 may be of a P-type instead of an N-type. In one case, the first transistor 21 is a P-channel metal oxide semiconductor field effect transistor (pMOSFET) while the second transistor 22 is an N-channel metal oxide semiconductor field effect transistor. In another case, the second transistor 22 is a P-channel metal oxide semiconductor field effect transistor while the first transistor 21 is an N-channel metal oxide semiconductor field effect transistor. In yet another case, the first transistor 21 and the second transistor 22 are P-channel metal oxide semiconductor field effect transistors. In the cases where the first transistor 21 is a P-channel metal oxide semiconductor field effect transistor, to write any one of the bit of the logic value “1” and the bit of the logic value “0” to the memory cell 200 as depicted in FIG. 3, the ground, instead of the supply voltage, is provided to the write word line (WWL) so as to make the first transistor 21 conducting. In the cases where the second transistor 22 is a P-channel metal oxide semiconductor field effect transistor, to read the bit of data from the memory cell 200 as depicted in FIG. 3, the read bit line (RBL) is pre-discharged to the ground voltage, and the supply voltage is provided to the read word line (RWL). If the bit of data kept at the storage node 23 is the bit of the logic value “1,” then the second transistor 22 would not conduct, and the read bit line (RBL) would stay pre-discharged to the ground voltage. If the bit of data kept at the storage node 23 is the bit of the logic value “0,” then the second transistor 22 would conduct, and the read bit line (RBL) would be charged by a power supply for supplying the supply voltage through the conducting second transistor 22 so as to rise to a voltage approaching the supply voltage.

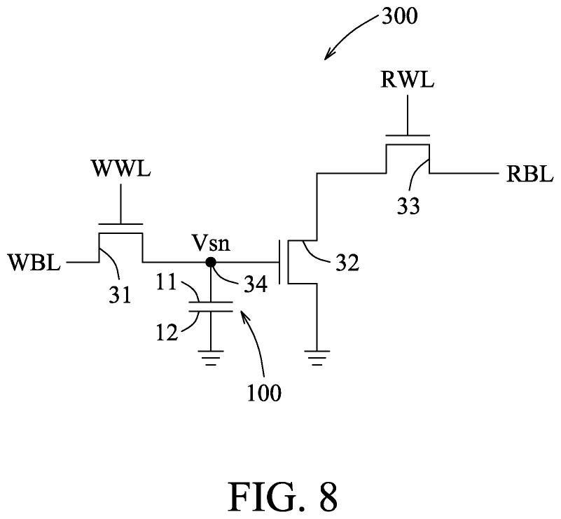

FIG. 8 is a circuit diagram illustrating a memory cell 300 in accordance with some embodiments. Referring to FIG. 8, the memory cell 300 has a 3T1C structure, and can be used in a gain cell random access memory. The memory cell 300 includes a first transistor 31, a second transistor 32, a third transistor 33 and the asymmetrical capacitor 100 as depicted in FIG. 1. The first transistor 31 (e.g., an N-channel metal oxide semiconductor field effect transistor) has a first terminal (e.g., a source terminal) that is connected to a write bit line (WBL), a second terminal (e.g., a drain terminal) that is connected to a storage node 34, and a control terminal (e.g., a gate terminal) that is connected to a write word line (WWL). The second transistor 32 (e.g., an N-channel metal oxide semiconductor field effect transistor) has a first terminal (e.g., a source terminal) that is connected to ground, a second terminal (e.g., a drain terminal), and a control terminal (e.g., a gate terminal) that is connected to the storage node 34. The third transistor 33 (e.g., an N-channel metal oxide semiconductor field effect transistor) has a first terminal (e.g., a source terminal) that is connected to the second terminal of the second transistor 32, a second terminal (e.g., a drain terminal) that is connected to a read bit line (RBL), and a control terminal (e.g., a gate terminal) that is connected to a read word line (RWL). The first electrode 11 of the asymmetrical capacitor 100 is connected to the storage node 34. The second electrode 12 of the asymmetrical capacitor 100 is connected to ground.

To write a bit of a logic value “1” to the memory cell 300, a supply voltage (>0 volts) is provided to the write bit line (WBL), and the supply voltage is further provided to the write word line (WWL) so as to make the first transistor 31 conducting. The bit of the logic value “1” is transmitted from the write bit line (WBL) to the storage node 34 through the conducting first transistor 31, so a voltage (Vsn) at the storage node 34 approaches the supply voltage. After the write “1” operation is performed on the memory cell 300, the bit of the logic value “1” is kept at the storage node 34.

To write a bit of a logic value “0” to the memory cell 300, a ground voltage of 0 volts is provided to the write bit line (WBL), and the supply voltage is provided to the write word line (WWL) so as to make the first transistor 31 conducting. The bit of the logic value “0” is transmitted from the write bit line (WBL) to the storage node 34 through the conducting first transistor 31, so the voltage (Vsn) at the storage node 34 approaches the ground voltage. After the write “0” operation is performed on the memory cell 300, the bit of the logic value “0” is kept at the storage node 34.

To read the bit of data from the memory cell 300, the read bit line (RBL) is precharged to the supply voltage, the supply voltage is provided to the read word line (RWL) so that the third transistor 33 would be conducting, and the ground voltage is provided to the write word line (WWL) so as to make the first transistor 31 non-conducting. If the bit of data kept at the storage node 34 is the bit of the logic value “1,” then the second transistor 32 and the third transistor 33 would conduct, and the read bit line (RBL) would be discharged by ground through the conducting second transistor 32 and the conducting third transistor 33 so as to fall to a voltage approaching the ground voltage. If the bit of data kept at the storage node is the bit of the logic value “0,” then the second transistor 32 would not conduct, and the read bit line (RBL) would stay precharged to the supply voltage.

Similar to the memory cell 200 as depicted in FIG. 3, the leakage current of the asymmetrical capacitor 100 is much smaller than the leakage current of a corresponding comparative capacitor when both of the memory cell 300 as depicted in FIG. 8 and a corresponding comparative memory cell store the bit of the logic value “1,” and is slightly larger than the leakage current of the comparative capacitor when both of the memory cell 300 as depicted in FIG. 8 and the comparative memory cell store the bit of the logic value “0,” so the voltage (Vsn) at the storage node 34 of the memory cell 300 as depicted in FIG. 8 decreases much slower over time and thus the memory cell 300 as depicted in FIG. 8 has better data retention performance as compared to the comparative memory cell after the write “1” operation is performed on both of the memory cell 300 as depicted in FIG. 8 and the comparative memory cell, and increases over time slightly faster as compared to the comparative memory cell after the write “0” operation is performed on both of the memory cell 300 as depicted in FIG. 8 and the comparative memory cell, and the memory cell 300 as depicted in FIG. 8 can have a larger read margin as compared to the comparative memory cell.

In some embodiments, one, two or all of the first transistor 31, the second transistor 32 and the third transistor 33 of the memory cell 300 as depicted in FIG. 8 may be of a P-type instead of an N-type. In one case, the first transistor 31 is a P-channel metal oxide semiconductor field effect transistor while the second transistor 32 and the third transistor 33 are N-channel metal oxide semiconductor field effect transistors. In another case, the second transistor 32 is a P-channel metal oxide semiconductor field effect transistor while the first transistor 31 and the third transistor 33 are N-channel metal oxide semiconductor field effect transistors. In yet another case, the third transistor 33 is a P-channel metal oxide semiconductor field effect transistor while the first transistor 31 and the second transistor 32 are N-channel metal oxide semiconductor field effect transistors. In still another case, the first transistor 31 and the second transistor 32 are P-channel metal oxide semiconductor field effect transistors while the third transistor 33 is an N-channel metal oxide semiconductor field effect transistor. In one other case, the first transistor 31 and the third transistor 33 are P-channel metal oxide semiconductor field effect transistors while the second transistor 32 is an N-channel metal oxide semiconductor field effect transistor. In a further case, the second transistor 32 and the third transistor 33 are P-channel metal oxide semiconductor field effect transistors while the first transistor 31 is an N-channel metal oxide semiconductor field effect transistor. In a different case, the first transistor 31, the second transistor 32 and the third transistor 33 are P-channel metal oxide semiconductor field effect transistors. In addition, in the cases where the second transistor 32 is a P-channel metal oxide semiconductor field effect transistor, the first terminal of the second transistor 32 is connected to a power supply for supplying the supply voltage, instead of to ground. In the cases where the first transistor 31 is a P-channel metal oxide semiconductor field effect transistor, to write any one of the bit of the logic value “1” and the bit of the logic value “0” to the memory cell 300 as depicted in FIG. 8, the ground, instead of the supply voltage, is provided to the write word line (WWL) so as to make the first transistor 31 conducting. In the cases where the second transistor 32 is an N-channel metal oxide semiconductor field effect transistor while the third transistor 33 is a P-channel metal oxide semiconductor field effect transistor, to read the bit of data from the memory cell 300 as depicted in FIG. 8, the read bit line (RBL) is precharged to the supply voltage, and the ground voltage is provided to the read word line (RWL) so that the third transistor 33 would be conducting. If the bit of data kept at the storage node 34 is the bit of the logic value “1,” then the second transistor 32 and the third transistor 33 would conduct, and the read bit line (RBL) would be discharged by ground through the conducting second transistor 32 and the conducting third transistor 33 so as to fall to a voltage approaching the ground voltage. If the bit of data kept at the storage node 34 is the bit of the logic value “0,” then the second transistor 32 would not conduct, and the read bit line (RBL) would stay precharged to the supply voltage. In the cases where the second transistor 32 is a P-channel metal oxide semiconductor field effect transistor while the third transistor 33 is an N-channel metal oxide semiconductor field effect transistor, to read the bit of data from the memory cell 300 as depicted in FIG. 8, the read bit line (RBL) is pre-discharged to the ground voltage, and the supply voltage is provided to the read word line (RWL) so that the third transistor 33 would be conducting. If the bit of data kept at the storage node 34 is the bit of the logic value “1,” then the second transistor 32 would not conduct, and the read bit line (RBL) would stay pre-discharged to the ground voltage. If the bit of data kept at the storage node 34 is the bit of the logic value “0,” then the second transistor 32 and the third transistor 33 would conduct, and the read bit line (RBL) would be charged by the power supply through the conducting second transistor 32 and the conducting third transistor 33 so as to rise to a voltage approaching the supply voltage. In the cases where both of the second transistor 32 and the third transistor 33 are P-channel metal oxide semiconductor field effect transistors, to read the bit of data from the memory cell 300 as depicted in FIG. 8, the read bit line (RBL) is pre-discharged to the ground voltage, and the ground voltage is provided to the read word line (RWL) so that the third transistor 33 would be conducting. If the bit of data kept at the storage node 34 is the bit of the logic value “1,” then the second transistor 32 would not conduct, and the read bit line (RBL) would stay pre-discharged to the ground voltage. If the bit of data kept at the storage node 34 is the bit of the logic value “0,” then the second transistor 32 and the third transistor 33 would conduct, and the read bit line (RBL) would be charged by the power supply through the conducting second transistor 32 and the conducting third transistor 33 so as to rise to a voltage approaching the supply voltage.

In accordance with some embodiments of the present disclosure, an asymmetrical capacitor includes a first electrode, a second electrode and a dielectric element. The dielectric element is sandwiched between the first electrode and the second electrode. The first electrode has a work function that is greater than a work function of the second electrode by at least 0.2 eV.

In accordance with some embodiments of the present disclosure, the work function of the first electrode is greater than the work function of the second electrode by at most 1.5 eV.

In accordance with some embodiments of the present disclosure, the first electrode and the second electrode are made of different materials.

In accordance with some embodiments of the present disclosure, the first electrode and the second electrode are made of a same material, but have different crystalline orientations.

In accordance with some embodiments of the present disclosure, the first electrode and the second electrode are made of a same material, but have different crystalline phases.

In accordance with some embodiments of the present disclosure, the first electrode and the second electrode are made of a same material, but have different composition ratios.

In accordance with some embodiments of the present disclosure, each of the first electrode and the second electrode is made of pure metal, refractory metal nitride, conductive oxide, or combinations thereof.

In accordance with some embodiments of the present disclosure, the dielectric element has a dielectric constant that is greater than or equal to 30.

In accordance with some embodiments of the present disclosure, the dielectric element is made of oxide, perovskite oxide, nitride, oxy-nitride, or combinations thereof.

In accordance with some embodiments of the present disclosure, the dielectric element includes a single layer that has a symmetrical crystalline phase structure.

In accordance with some embodiments of the present disclosure, the dielectric element includes a plurality of layers, each of which has a symmetrical crystalline phase structure.

In accordance with some embodiments of the present disclosure, the dielectric element is made of a compound material that has a morphotropic phase boundary.

In accordance with some embodiments of the present disclosure, an asymmetrical capacitor includes a first electrode, a second electrode and a dielectric element. The dielectric element is sandwiched between the first electrode and the second electrode. The first electrode and the second electrode have different work functions, and a difference between the work function of the first electrode and the work function of the second electrode falls within a range of from 0.2 eV to 1.5 eV.

In accordance with some embodiments of the present disclosure, the first electrode and the second electrode are made of different materials.

In accordance with some embodiments of the present disclosure, the first electrode and the second electrode are made of a same material, but differ from each other in at least one of crystalline orientation, crystalline phase or composition ratio.

In accordance with some embodiments of the present disclosure, the dielectric element has a dielectric constant that is greater than or equal to 30.

In accordance with some embodiments of the present disclosure, a memory cell includes a first transistor, a second transistor and an asymmetrical capacitor. The first transistor has a first terminal, a second terminal and a control terminal. The second transistor has a first terminal, a second terminal, and a control terminal that is connected to the second terminal of the first transistor. The asymmetrical capacitor includes a first electrode that is connected to the second terminal of the first transistor, a second electrode, and a dielectric element that is sandwiched between the first electrode and the second electrode. The first electrode of the asymmetrical capacitor has a work function that is greater than a work function of the second electrode of the asymmetrical capacitor by at least 0.2 eV.

In accordance with some embodiments of the present disclosure, the first electrode and the second electrode of the asymmetrical capacitor are made of different materials.

In accordance with some embodiments of the present disclosure, the first electrode and the second electrode of the asymmetrical capacitor are made of a same material, but differ from each other in at least one of crystalline orientation, crystalline phase or composition ratio.

In accordance with some embodiments of the present disclosure, the dielectric element of the asymmetrical capacitor has a dielectric constant that is greater than or equal to 30.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An asymmetrical capacitor comprising:
a first electrode;
a second electrode; and
a dielectric element sandwiched between the first electrode and the second electrode;
wherein the first electrode has a work function that is greater than a work function of the second electrode by at least 0.2 eV.

2. The asymmetrical capacitor according to claim 1, wherein the work function of the first electrode is greater than the work function of the second electrode by at most 1.5 eV.

3. The asymmetrical capacitor according to claim 1, wherein the first electrode and the second electrode are made of different materials.

4. The asymmetrical capacitor according to claim 1, wherein the first electrode and the second electrode are made of a same material, but have different crystalline orientations.

5. The asymmetrical capacitor according to claim 1, wherein the first electrode and the second electrode are made of a same material, but have different crystalline phases.

6. The asymmetrical capacitor according to claim 1, wherein the first electrode and the second electrode are made of a same material, but have different composition ratios.

7. The asymmetrical capacitor according to claim 1, wherein each of the first electrode and the second electrode is made of pure metal, refractory metal nitride, conductive oxide, or combinations thereof.

8. The asymmetrical capacitor according to claim 1, wherein the dielectric element has a dielectric constant that is greater than or equal to 30.

9. The asymmetrical capacitor according to claim 1, wherein the dielectric element is made of oxide, perovskite oxide, nitride, oxy-nitride, or combinations thereof.

10. The asymmetrical capacitor according to claim 1, wherein the dielectric element includes a single layer that has a symmetrical crystalline phase structure.

11. The asymmetrical capacitor according to claim 1, wherein the dielectric element includes a plurality of layers, each of which has a symmetrical crystalline phase structure.

12. The asymmetrical capacitor according to claim 1, wherein the dielectric element is made of a compound material that has a morphotropic phase boundary.

13. An asymmetrical capacitor comprising:
a first electrode;
a second electrode; and
a dielectric element sandwiched between the first electrode and the second electrode;
wherein the first electrode and the second electrode have different work functions, and a difference between the work function of the first electrode and the work function of the second electrode falls within a range of from 0.2 eV to 1.5 eV.

14. The asymmetrical capacitor according to claim 13, wherein the first electrode and the second electrode are made of different materials.

15. The asymmetrical capacitor according to claim 13, wherein the first electrode and the second electrode are made of a same material, but differ from each other in at least one of crystalline orientation, crystalline phase or composition ratio.

16. The asymmetrical capacitor according to claim 8, wherein the dielectric element has a dielectric constant that is greater than or equal to 30.

17. A memory cell comprising:
a first transistor having a first terminal, a second terminal and a control terminal;
a second transistor having a first terminal, a second terminal, and a control terminal that is connected to the second terminal of the first transistor; and
an asymmetrical capacitor including
a first electrode connected to the second terminal of the first transistor,
a second electrode, and
a dielectric element sandwiched between the first electrode and the second electrode;
wherein the first electrode of the asymmetrical capacitor has a work function that is greater than a work function of the second electrode of the asymmetrical capacitor by at least 0.2 eV.

18. The memory cell according to claim 17, wherein the first electrode and the second electrode of the asymmetrical capacitor are made of different materials.

19. The memory cell according to claim 17, wherein the first electrode and the second electrode of the asymmetrical capacitor are made of a same material, but differ from each other in at least one of crystalline orientation, crystalline phase or composition ratio.

20. The memory cell according to claim 17, wherein the dielectric element of the asymmetrical capacitor has a dielectric constant that is greater than or equal to 30.
